(19) United States
(12) Patent Application Publication
(10) Pub. No.: US 2010/0258893 A1
(43) Pub. Date: Oct. 14, 2010

(54) SOLID-STATE IMAGING DEVICE MANUFACTURING METHOD, SOLID-STATE IMAGING DEVICE, AND ELECTRONIC APPARATUS

(75) Inventor: Ken Sawada, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/754,910

(22) Filed: Apr. 6, 2010

(30) Foreign Application Priority Data
Apr. 13, 2009 (JP) 2009-096610

(51) Int. Cl. H01L 27/146; H01L 31/18

(52) U.S. Cl. 257/440; 438/57; 257/E27.133; 257/E21.211

(57) ABSTRACT

A method of manufacturing a solid-state imaging device includes: a first step of forming a recess portion on a top surface of a semiconductor substrate; a second step of selectively forming an impurity region of a first conductivity type in a lower portion of the recess portion by introducing impurities from a bottom surface of the recess portion; and a third step of forming a semiconductor layer in the recess portion, thus forming a photoelectric conversion portion which includes the impurity region and the semiconductor layer.

### BACKGROUND OF THE INVENTION

1. Field of the Invention

The present invention relates to a solid-state imaging device manufacturing method, a solid-state imaging device, and an electronic apparatus. More particularly, the present invention relates to a method of manufacturing a solid-state imaging device having a deep photoelectric conversion portion, a solid-state imaging device obtained by the manufacturing method, and an electronic apparatus having the solid-state imaging device.

2. Description of the Related Art

In solid-state imaging devices, particularly in CMOS image sensors, demands for higher quality such as higher sensitivity are increasing in line with demands for more pixels and a smaller chip size. To comply with such demands, in solid-state imaging devices, pixels are being further miniaturized, and 1.5 μm-square pixels or smaller are being developed and commercialized.

However, when the size of pixels used in a solid-state imaging device decreases, the amount of light entering photodiodes arranged in each pixel decreases. For this reason, in micro-pixels having a pixel size of 1.2 μm square or smaller, sensitivity degradation on the longer-wavelength side is severe, so that a sensitivity loss in pixels for sensing red light having a longer wavelength is regarded as a serious problem.

The sensitivity on the longer-wavelength side can be improved by a method of setting an ion implantation energy at the time of forming a photodiode in multiple levels so that an impurity region serving as a photoelectric conversion portion is formed at a deeper position. However, there is a limit on the formation depth of the impurity region because the implanted impurities may be diffused in the horizontal direction, which may result in increased bulk color-mixture.

To solve this problem, JP-A-9-213923 discloses a configuration in which a top surface of a semiconductor substrate serving as a formation region of a photodiode is etched to form a recess portion, and an n-type semiconductor serving as a photoelectric conversion portion is grown in the recess portion to a necessary thickness (see, particularly, FIG. 2 and Paragraphs [0020] to [0035]). JP-A-9-213923 describes that since a material having a greater absorption coefficient than silicon is used as the n-type semiconductor to be grown, the necessary thickness of the n-type semiconductor is small, and thus the n-type semiconductor will not bulge out from the top surface of the semiconductor substrate.

### SUMMARY OF THE INVENTION

However, the above-described configuration in which the photoelectric conversion portion is formed by the n-type semiconductor that is grown in the recess portion of the semiconductor substrate has the following problems.

Specifically, when as the n-type semiconductor, silicon is grown in the recess portion of a semiconductor substrate made from silicon, a top surface of the n-type semiconductor that is formed to a necessary thickness will bulge out from the top surface of the semiconductor substrate. The photodiode formed in such a state may provide poor flatness necessary for a base on which a wiring layer, an optical system including a lens system, and the like are formed. Therefore, the formation process is difficult, and design of the optical system is also difficult.

Moreover, when a material having a sufficiently greater absorption coefficient than silicon is grown in the recess portion of the semiconductor substrate made from silicon, compound n-type semiconductors such as GaAs, GaP, and InGaAsP can be candidate materials for the n-type semiconductor. However, in general, when compound semiconductors are heterogeneously grown in a very small recess portion made from single-crystalline silicon, interface states, defects, or the like will occur. In photodiodes, such interface states or defects in the photoelectric conversion portion may become the cause of pixel defects and image-quality deterioration.

It is therefore desirable to provide a method of manufacturing a solid-state imaging device capable of forming a deep photoelectric conversion portion without affecting surface flatness. It is also desirable to provide a solid-state imaging device capable of achieving miniaturization of pixels while providing high image quality by the manufacturing method.

A method of manufacturing a solid-state imaging device according to an embodiment of the present invention includes the steps of forming a recess portion on a top surface of a semiconductor substrate; selectively forming an impurity region of a first conductivity type in a lower portion of the recess portion by introducing impurities from a bottom surface of the recess portion; and forming a semiconductor layer in the recess portion, thus forming a photoelectric conversion portion which includes the impurity region and the semiconductor layer.

In the method, since the impurity region of the first conductivity type is formed by impurity diffusion from the bottom portion of the recess portion formed in the semiconductor substrate, it is possible to form the impurity region at a further deeper position in the semiconductor substrate. In this way, by the impurity region and the semiconductor layer formed thereon, it is possible to obtain a photoelectric conversion portion that reaches from the top surface of the semiconductor substrate to a further deeper position while maintaining surface flatness of the semiconductor substrate.

A solid-state imaging device according to another embodiment of the present invention includes an impurity region of a first conductivity type formed in a portion of a semiconductor substrate disposed lower than a bottom surface of a recess portion formed in the semiconductor substrate; and a semiconductor layer of the first conductivity type formed in the recess portion, in which a photoelectric conversion portion is formed by the impurity region and the semiconductor layer. An electronic apparatus according to another embodiment of the present invention includes such a solid-state imaging device.

As described above, according to the embodiments of the present invention, it becomes easy to form a wiring layer, an optical system, and the like on the semiconductor substrate, in which surface flatness is maintained, with high accuracy. Moreover, by the photoelectric conversion portion that extends from the top surface of the semiconductor substrate to a further deeper position, it is possible to sense longer-wavelength light with high sensitivity. As a result, high-quality imaging is made possible in miniaturized pixels.

### BRIEF DESCRIPTION OF THE DRAWINGS

FIGS. 1A to 1D are first cross-sectional views showing the process steps according to the first embodiment.

FIGS. 2A and 2B are second cross-sectional views showing the process steps according to the first embodiment.

FIGS. 3A and 3B are third cross-sectional views showing the process steps according to the first embodiment.

FIGS. 4A and 4B are fourth cross-sectional views showing the process steps according to the first embodiment.

FIGS. 5A and 5B are fifth cross-sectional views showing the process steps according to the first embodiment.

FIGS. 6A to 6C are sixth cross-sectional views showing the process steps according to the first embodiment.

FIGS. 7A and 7B are first cross-sectional views showing the process steps of a manufacturing method according to the second embodiment.

FIGS. 8A and 8B are second cross-sectional views showing the process steps according to the second embodiment.

FIGS. 9A and 9B are third cross-sectional views showing the process steps according to the second embodiment.

FIGS. 10A and 10B are fourth cross-sectional views showing the process steps according to the second embodiment.

FIG. 11 is a fifth cross-sectional view showing the process step according to the second embodiment.

FIG. 12 is a diagram showing a configuration of an exemplary apparatus according to the third embodiment.

### DESCRIPTION OF THE PREFERRED EMBODIMENTS

Hereinafter, embodiments of the present invention will be described in the following order.

1. First Embodiment (Recess Portion is Provided in Only Photosensitive Region of Red Pixel)

2. Second Embodiment (Recess Portions Having Different Depths are Provided in Photosensitive Regions of Respective Color Pixels)

3. Third Embodiment (Exemplary Configuration of Electronic Apparatus Using Solid-State Imaging Device)

That is, the manufacturing method of solid-state imaging devices such as CMOS image sensors will be described in the first and second embodiments, and thereafter, the configuration of a solid-state imaging device obtained by the manufacturing method will be described. In the following description, n and p types will be referred to as the first and second conductivity types, respectively; however, the conductivity types may be reversed.

### 1. First Embodiment

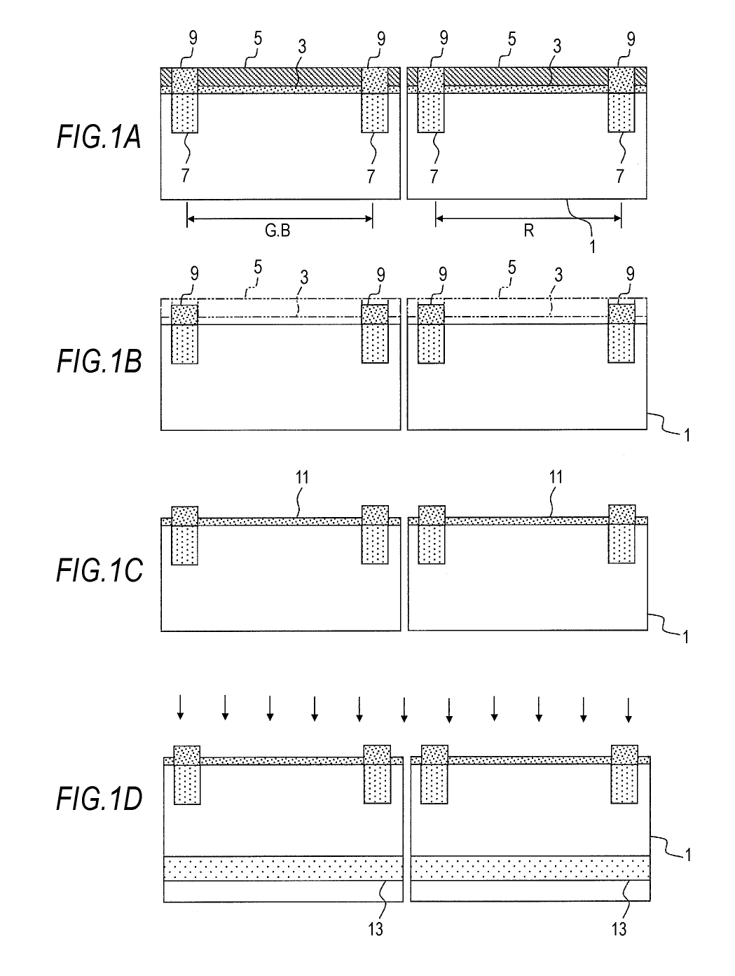

The method of manufacturing a solid-state imaging device according to the first embodiment will be described with reference to the process diagrams shown in FIGS. 1A to 6C. In the drawings, the cross-sectional views of the two pixels, the red pixel R sensitive to red light and the green or blue pixels G and B sensitive to green or blue light, are shown.

First, as shown in FIG. 1A, a silicon nitride film 5 (thickness: about 150 nm) is formed on a semiconductor substrate 1 made from a single-crystalline silicon with a silicon oxide film 3 disposed therebetween. Next, these laminated films are patterned, and impurities are introduced on a top surface side of the semiconductor substrate 1 by an ion implantation using the patterned film as a mask, thus forming a diffusion barrier layer 7 that separates respective pixel portions G, B, and R from each other. At that time, boron ions (B⁺) are introduced at an implantation dose amount of 1E13/cm² with an implantation energy of 10 keV.

After that, a silicon oxide film is formed on the entire surface of the semiconductor substrate 1, and the silicon oxide film is subjected to CMP (chemical mechanical polishing) using the silicon nitride film 5, which was used as a mask, as a stopper, whereby a device separation layer 9 made from a silicon oxide is formed on the diffusion barrier layer 7.

Subsequently, as shown in FIG. 1B, the silicon nitride film 5 used as a stopper for CMP and the silicon oxide film 7 disposed thereunder are delaminated and removed. In this way, the top surface of the semiconductor substrate 1 is exposed. Although the device separation layer 9 made from a silicon oxide is also partially slightly removed by the delamination and removal of the silicon oxide film 7, the device separation layer 9 remains on the semiconductor substrate 1.

After that, as shown in FIG. 1C, a silicon oxide film which serves as a protection film (a so called implantation-through film) for an ion implantation performed later is formed to a thickness of about 10 nm on the exposed surface of the semiconductor substrate 1.

Subsequently, as shown in FIG. 1D, by a high-energy ion implantation, p-type impurity regions 13 which serve as impurity regions of the second conductivity type for overflow prevention are formed at a predetermined depth position of the pixel portions of the semiconductor substrate 1. At that time, boron ions (B⁺) are introduced at an implantation dose amount of 1E11/cm² with a high implantation energy of 2000 keV in a state where portions of the semiconductor substrate 1 other than the pixel portions are covered with a resist pattern (not shown).

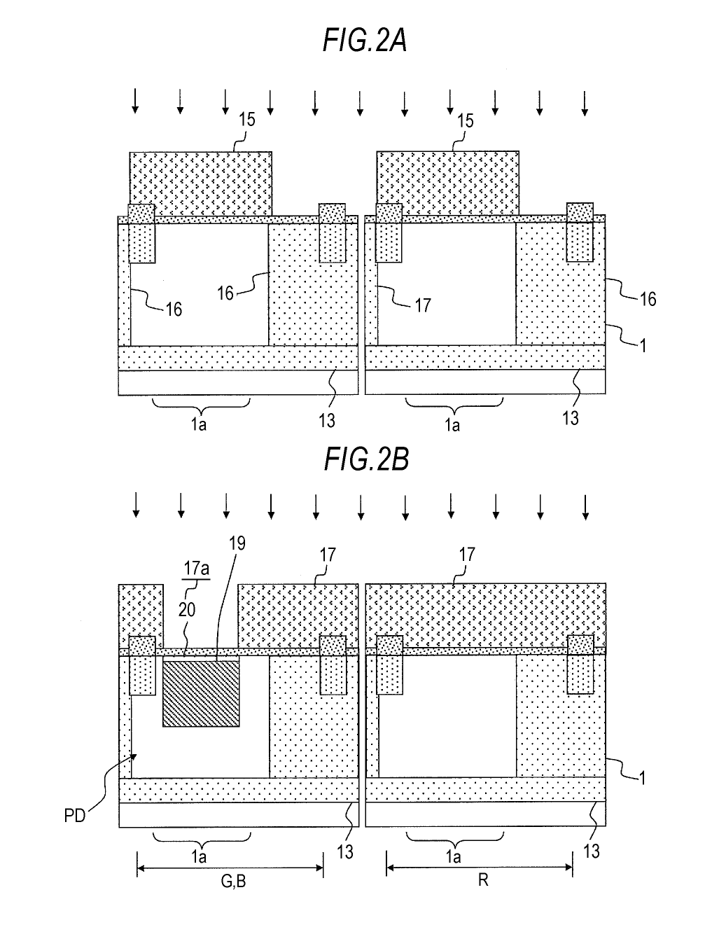

After that, as shown in FIG. 2A, regions (i.e., light-sensitive regions 1a) of the respective pixel portions in which a photoelectric conversion portion of a photodiode will be formed are covered with a resist pattern 15, and p-well regions 16 which serve as well regions of the second conductivity type are formed around the light-sensitive regions 1a. The p-well regions 16 are formed into a profile such as to have a depth extending from the top surface of the semiconductor substrate 1 to the p-type impurity regions 13 by performing an ion implantation with multiple implantation energy levels. For example, boron ions (B⁺) are introduced by a 3-step ion implantation; that is, the ions are introduced at an implantation dose amount of 2E12/cm² with an implantation energy of 1500 keV, at an implantation dose amount of 2E12/cm² with an implantation energy of 700 keV, and at an implantation dose amount of 3E12/cm² with an implantation energy of 200 keV. After the ion implantation is completed, the resist pattern 15 is removed.

Subsequently, as shown in FIG. 2B, a resist pattern 17 is formed so as to cover the red pixel R and have aperture portions 17a on the light-sensitive regions 1a of the green pixel G and the blue pixel B. Then, by performing an ion implantation on the resist pattern 17, n-type impurity regions 19 which serve as impurity regions of the first conductivity type are formed in the light-sensitive regions 1a of the green pixel G and the blue pixel B.

The n-type impurity regions 19 are formed into a desired profile such as to extend from the top surface of the semiconductor substrate 1 to a predetermined depth by performing an ion implantation with multiple implantation energy levels. For example, phosphorus ions (P⁺) are introduced by a 3-step ion implantation; that is, the ions are introduced at an implantation dose amount of 1E11/cm² with an implantation energy of 1200 keV, at an implantation dose amount of 3E11/cm² with an implantation energy of 600 keV, and at an implantation dose amount of 4E11/cm² with an implantation energy of 300 keV. The n-type impurity regions 19 are preferably formed at a certain distance from the p-type impurity regions 13.

Subsequently, by an ion implantation using the resist pattern 17 as a mask, surface p-type regions 20 are formed on top surface layers of the n-type impurity regions 19. At that time, for example, boron fluoride ions (BF²⁺) are introduced at an implantation dose amount of about 2E12/cm² with an implantation energy of 50 keV. After the ion implantation is completed, the resist pattern 17 is removed.

In this way, a photodiode PD in which a photoelectric conversion portion is formed by the n-type impurity region 19 is formed in the light-sensitive regions 1a of the green pixel G and the blue pixel B. The photodiode PD has a configuration such that the photoelectric conversion portion is formed by only the n-type impurity region 19.

On the other hand, in the light-sensitive region 1a of the red pixel R, the photodiode is formed by the following method.

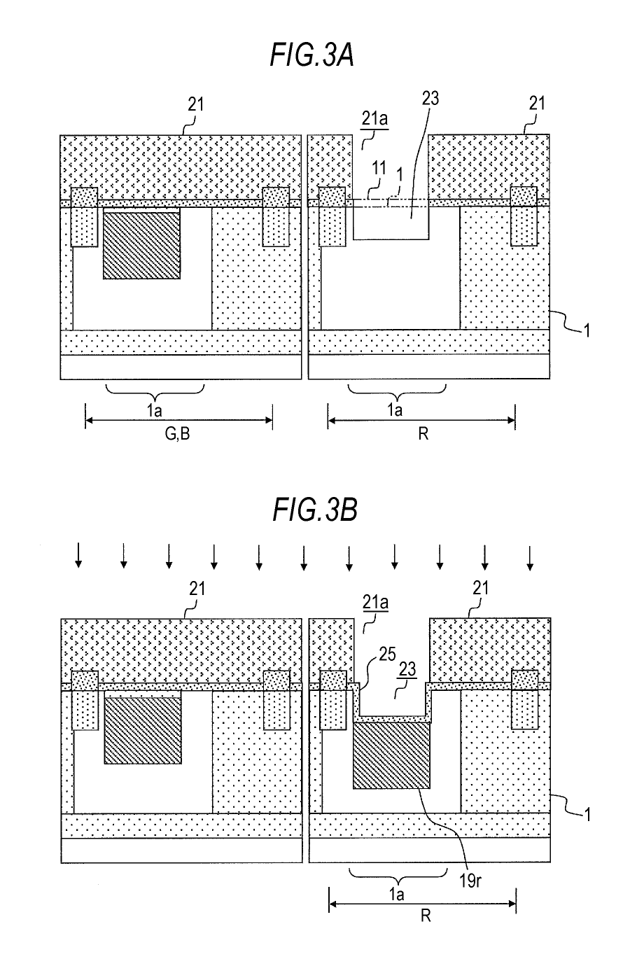

First, as shown in FIG. 3A, a resist pattern 21 is formed so as to cover the green pixel G and the blue pixel B and have an aperture portion 21a on the light-sensitive region 1a of the red pixel R. After that, the silicon oxide film 11 and the top surface of the semiconductor substrate 1 are etched using the resist pattern 21 as a mask, thus forming a recess portion 23 on the top surface of the light-sensitive region 1a in the red pixel R. This etching is carried out by a dry etching such as a RIE (reactive ion etching). Moreover, the recess portion 23 has a depth of about 500 nm to 1 μm.

Subsequently, as shown in FIG. 3B, a silicon oxide film which serves as a protection film (a so called implantation-through film) for an ion implantation performed later is formed in such a manner as to cover the semiconductor substrate 1 exposed to the inner walls of the recess portion 23.

After that, by performing an ion implantation on the resist pattern 21, an n-type impurity region 19r which serves as an impurity regions of the first conductivity type is formed in only the light-sensitive region 1a of the red pixel R. The n-type impurity region 19r is formed into a desired profile such as to extend from the bottom surface of the recess portion 23 to a predetermined depth by performing an ion implantation with multiple implantation energy levels. Such a multi-step ion implantation can be performed by the same method as the forming of the n-type impurity regions 19 of the green pixel G and the blue pixel B. For example, phosphorus ions (P⁺) are introduced by a 3-step ion implantation; that is, the ions are introduced at an implantation dose amount of 1E11/cm² with an implantation energy of 1200 keV, at an implantation dose amount of 3E11/cm² with an implantation energy of 600 keV, and at an implantation dose amount of 4E11/cm² with an implantation energy of 300 keV. The n-type impurity region 19r is preferably formed at a certain distance from the p-type impurity region 13. After the ion implantation is completed, the resist pattern 21 is removed.

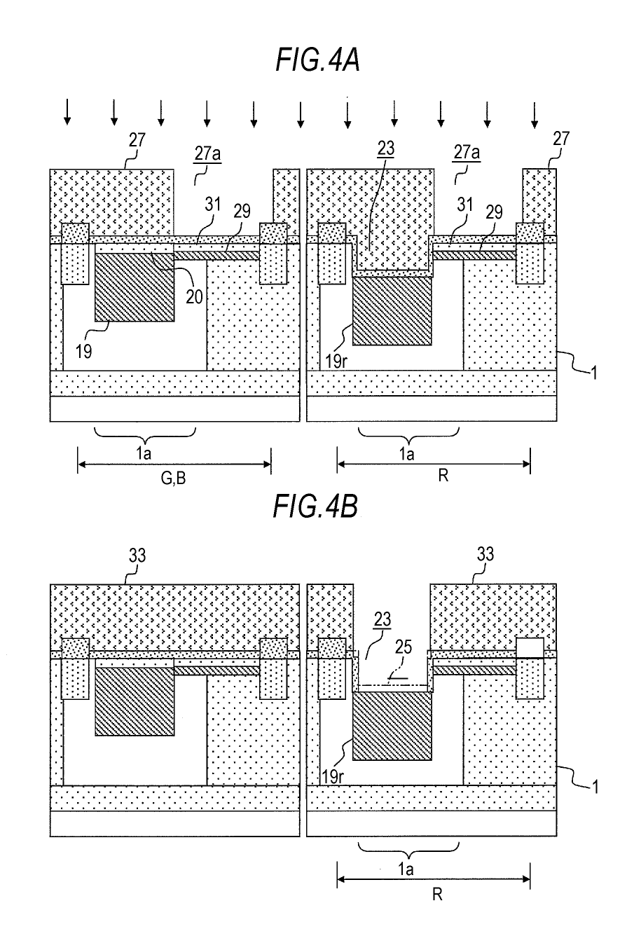

Next, as shown in FIG. 4A, a resist pattern 27 which has aperture portions 27a on regions adjacent to the light-sensitive regions 1a of the respective pixels is formed on the semiconductor substrate 1. Subsequently, by an ion implantation using the resist pattern 27 as a mask, n-type channel regions 29 which serve as channel regions of the first conductivity type are formed on the top surface layer of the semiconductor substrate 1. At that time, for example, arsenic ions (As⁺) are introduced at an implantation dose amount of about 5E11/cm² with an implantation energy of 150 keV.

In this embodiment, in the green pixel G and the blue pixel B, the n-type channel regions 29 are formed so as to be connected to the n-type impurity regions 19. On the other hand, in the red pixel R, the n-type channel region 29 is formed so as to reach a sidewall of the recess portion 23. Moreover, in the red pixel R, the n-type channel region 29 may be connected to the n-type impurity region 19r that is disposed under the recess portion 23.

Subsequently, by an ion implantation using the resist pattern 27 as a mask, surface p-type regions 31 are formed on top surface layers of the n-type impurity regions 29. At that time, for example, boron fluoride ions (BF²⁺) are introduced at an implantation dose amount of about 2E12/cm² with an implantation energy of 50 keV.

In this embodiment, in the green pixel G and the blue pixel B, the surface p-type regions 31 are formed so as to be connected to the surface p-type regions 20 that covers the n-type impurity regions 19. On the other hand, in the red pixel R, the surface p-type region 31 is formed so as to reach the sidewall of the recess portion 23. After the ion implantation is completed, the resist pattern 27 is removed.

In this way, in the green pixel G and the blue pixel B, the n-type channel regions 29 and the surface p-type regions 31 are formed to be in contact with the n-type impurity regions 19 of the photodiodes PDs that are formed on the top surface side of the semiconductor substrate 1. On the other hand, in the red pixel R, the n-type channel region 29 and the surface p-type region 31 are formed so as to reach the sidewall of the recess portion 23 that are formed on the top surface of the semiconductor substrate 1.

Next, as shown in FIG. 4B, a resist pattern 33 is formed so as to have an aperture portion 33a on the light-sensitive region 1a of the red pixel R. Here, it is important to form the resist pattern 33 so as to completely cover portions which are disposed above the top surface of the semiconductor substrate 1 and located at the upper periphery of the recess portion 23. For this reason, the aperture shape of the aperture portion 33a may be smaller than the aperture shape of the recess portion 23.

Subsequently, the silicon oxide film 25 at the bottom of the recess portion 23 is etched and removed using the resist pattern 33 as a mask so that the top surface of the semiconductor substrate 1 in which the n-type impurity region 19r is formed is exposed to the bottom portion of the recess portion 23. This etching exposes only the bottom portion of the recess portion 23 by using an anisotropic etching such as an RIE (reactive ion etching). After the etching is completed, the resist pattern 33 is removed.

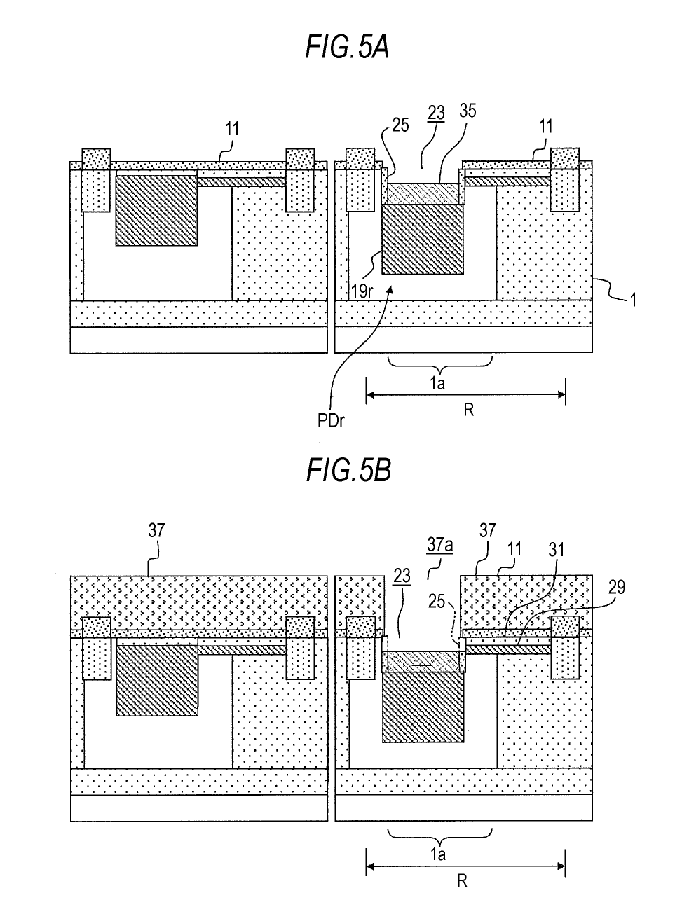

Next, as shown in FIG. 5A, using the silicon oxide films 11 and 25 as a mask, an n-type semiconductor layer 35 is formed on the exposed surface of the semiconductor substrate 1, specifically, so as to be in contact with the n-type impurity region 19r which is exposed to the bottom surface of the recess portion 23 formed in the light-sensitive region 1a of the red pixel R. In this embodiment, the n-type semiconductor layer 35 is grown so that the inside of the recess portion 23 is not completely filled but a recess portion 23 having a depth of 200 to 300 nm remains above the recess portion 23.

The n-type semiconductor layer 35 formed in this step may be made from crystalline silicon including polysilicon, crystalline silicon-germanium, and the like. Particularly, when the semiconductor substrate 1 is made from single-crystalline silicon, it is preferable that the n-type semiconductor layer 35 is made from silicon which is of the same atomic species. By doing so, it is possible to form the n-type semiconductor layer 35 without defects. When the n-type semiconductor layer 35 is made from silicon-germanium, it is preferable to control the composition ratio of germanium to be 200 or less. By doing so, it is not only possible to decrease the growth temperature compared with silicon while maintaining substantially the same absorption coefficient as silicon at a wavelength near 600 nm, but also to prevent diffusion of impurities in the impurity regions formed in the previous steps.

When forming the n-type semiconductor layer 35, by introducing n-type impurities into an atmospheric gas used at the time of growing crystals on the semiconductor substrate 1, the n-type semiconductor layer 35 containing n-type impurities in advance is formed so as to be in contact with the n-type impurity region 19r.

Moreover, the n-type semiconductor layer 35 may be formed by forming a semiconductor layer without containing n-type impurities by crystal growing, and thereafter, introducing n-type impurities into the semiconductor layer by an ion implantation or the like. At that time, the n-type semiconductor layer 35 is formed so as to be in contact with the n-type impurity region 19r under ion implantation conditions in which arsenic ions (As⁺) are introduced at an implantation dose amount of about 4E12/cm² with an implantation energy of 180 keV. When performing such an ion implantation, a resist pattern may be used as a mask if necessary.

Subsequently, as shown in FIG. 5B, a resist pattern 37 is formed so as to have an aperture portion 37a on the light-sensitive region 1a of the red pixel R. Here, it is important to form the resist pattern 37 so as to expose the silicon oxide film 25 that covers the inner walls of the recess portion 23.

After that, the silicon oxide film 25 on the sidewalls of the recess portion 23 is etched and removed using the resist pattern 37 as a mask so that the n-type channel region 29 on the sidewalls of the recess portion 23 and portions of the semiconductor substrate 1 in which the surface p-type region 31 is formed are exposed. This etching is carried by an isotropic etching such as a wet etching. When the silicon oxide 11 at the upper periphery of the recess portion 23 is exposed through the resist pattern 37, the etching is stopped in a state in which the silicon oxide 25 on the sidewalls of the recess portion 23 is removed and the silicon oxide 11 at the upper periphery of the recess portion 23 remains. After the etching is completed, the resist pattern 37 is removed.

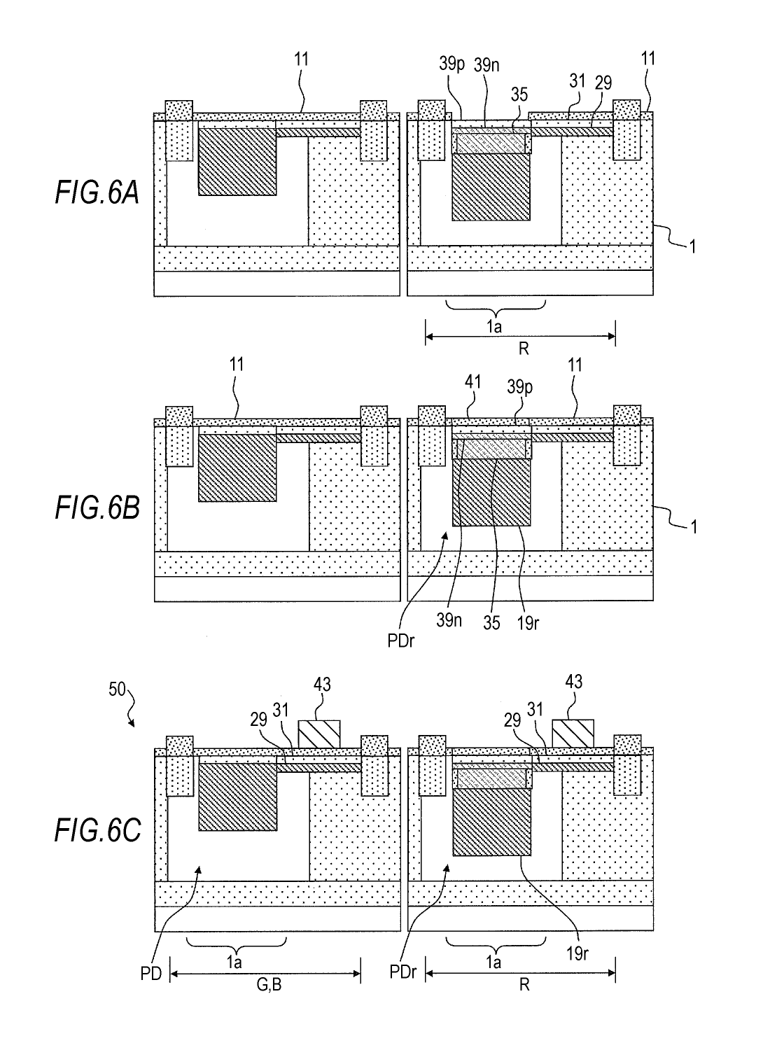

Next, as shown in FIG. 6A, using the silicon oxide film 11 as a mask, another n-type semiconductor layer 39n is formed on the n-type semiconductor layer 35 so as to be connected to the n-type channel region 29. Subsequently, a p-type semiconductor layer which becomes a surface p-type region 39p is formed so as to be connected to the surface p-type region 31. At that time, the n-type semiconductor layer 39n and the surface p-type region 39p are grown in that order so that the inside of the recess portion 23 is filled and they are formed to approximately the same height as the top surface of the semiconductor substrate 1.

The n-type semiconductor layer 39n and the surface p-type region 39p formed in this step are made from single-crystalline or poly-crystalline silicon, crystalline silicon-germanium, or the like, similarly to the n-type semiconductor layer 35 formed previously, and particularly, they are preferably made from silicon which is of the same atomic species as the semiconductor substrate 1.

In addition, when forming the n-type semiconductor layer 39n and the surface p-type region 39p, impurities may be introduced into an atmospheric gas used at the time of growing crystals so that they have respective conductivity types. Moreover, they may be formed by forming a semiconductor layer without containing impurities, and thereafter, introducing p-type impurities or n-type impurities into the semiconductor layer.

Subsequently, as shown in FIG. 6B, a silicon oxide film 41 is formed to a thickness of about 10 nm in such a manner as to cover the surface p-type region 39p. Here, the silicon oxide film 41 may be formed so as to cover only the surface p-type region 39p as shown in the drawing and may be formed over the entire surface of the semiconductor substrate 1.

In this way, a photodiode PDr in which a photoelectric conversion portion is formed by the n-type impurity region 19r provided under the bottom portion of the recess portion 23 and the n-type semiconductor layers 35 and 39n filling the inside of the recess portion 23 is formed in the light-sensitive region 1a of the red pixel R. Moreover, the surface p-type region 39p on the n-type semiconductor layer 39n serves as a hole-accumulation layer.

Thereafter, as shown in FIG. 6C, read-gate electrodes 43, other necessary gate electrodes, and wirings are formed on a portion of each pixel where the n-type channel region 29 and the surface p-type region 31 are laminated. Although not shown in the drawing, in addition to the above-mentioned elements, an optical system including a lens system is formed, and color filters that transmit desired wavelengths of light are formed on the respective light-sensitive regions 1a of the pixels R, G, and B, whereby a solid-state imaging device 50 is produced.

The solid-state imaging device 50 produced thus has the red pixel R, the green pixel G, and the blue pixel B. Among them, in the red pixel R, the photodiode PDr is provided in which the photoelectric conversion portion is formed by the n-type impurity region 19r that is disposed under the recess portion 23 formed on the top surface of the semiconductor substrate 1 and a laminated structure of the n-type semiconductor layers 35 and 39n that are provided in the recess portion 23 in a state of being connected to the n-type impurity region 19r.

When forming the photoelectric conversion portion in such a red pixel R, by performing an impurity diffusion (ion implantation) from the bottom portion of the recess portion 23 that is formed in the semiconductor substrate 1, it is possible to form the n-type impurity region 19r at a further deeper position in the semiconductor substrate 1. By doing so, it is possible to suppress horizontal diffusion of implanted impurities compared to a case of forming the n-type impurity region to approximately the same depth by an ion implantation with higher energy than that is necessary when the ion implantation is performed from the top surface of the semiconductor substrate 1.

For example, when the n-type impurity region 19r is formed to approximately the same depth by performing an ion implantation from the top surface of the semiconductor substrate 1, it is necessary to increase the implantation energy of phosphorus ions (P⁺) as high as 2000 keV to 3500 keV. For this reason, impurities are likely to diffuse in the horizontal direction. On the contrary, in the first embodiment, since the impurity diffusion is performed from the bottom portion of the recess portion 23, the implantation energy of phosphorus ions (P⁺) is 1200 keV or less, and an effective implantation depth is small. Therefore, it is possible to suppress horizontal diffusion of impurities.

Moreover, as seen above, by the n-type impurity region 19r in which horizontal diffusion of impurities is suppressed, and the n-type semiconductor layers 35 and 39n formed on the upper part of the n-type impurity region 19r, it is possible to obtain a photoelectric conversion portion having a depth that extends from a deeper position of the semiconductor substrate 1 to the top surface thereof.

Furthermore, since the laminated structure of the n-type semiconductor layers 35 and 39n has approximately the same height as the top surface of the semiconductor substrate 1, it is possible to maintain surface flatness of the semiconductor substrate 1.

In this way, it becomes easy to form a wiring layer, an optical system, and the like on the semiconductor substrate 1, in which surface flatness is maintained, with high accuracy. Moreover, by the photoelectric conversion portion having a depth that extends from a deeper position of the semiconductor substrate 1 to the top surface thereof, it is possible to sense longer-wavelength light with high sensitivity when red light is received. As a result, high-quality imaging is made possible in miniaturized pixels.

In the first embodiment, after the recess portion 23 and the n-type impurity region 19 are formed, and the n-type channel region 29 and the surface p-type region 31 are formed in the light-sensitive region 1a, the n-type semiconductor layers 35 and 39n and the surface p-type region 39p are formed. However, in the present invention, the same advantage can be obtained as long as after the recess portion 23 is formed, and the n-type impurity region 19 is formed on the bottom portion of the recess portion 23, the n-type semiconductor layers 35 and 39n are formed in the recess portion 23. Therefore, the order of forming the n-type channel region 29, the surface p-type region 31, and the like is not particularly limited.

### 2. Second Embodiment

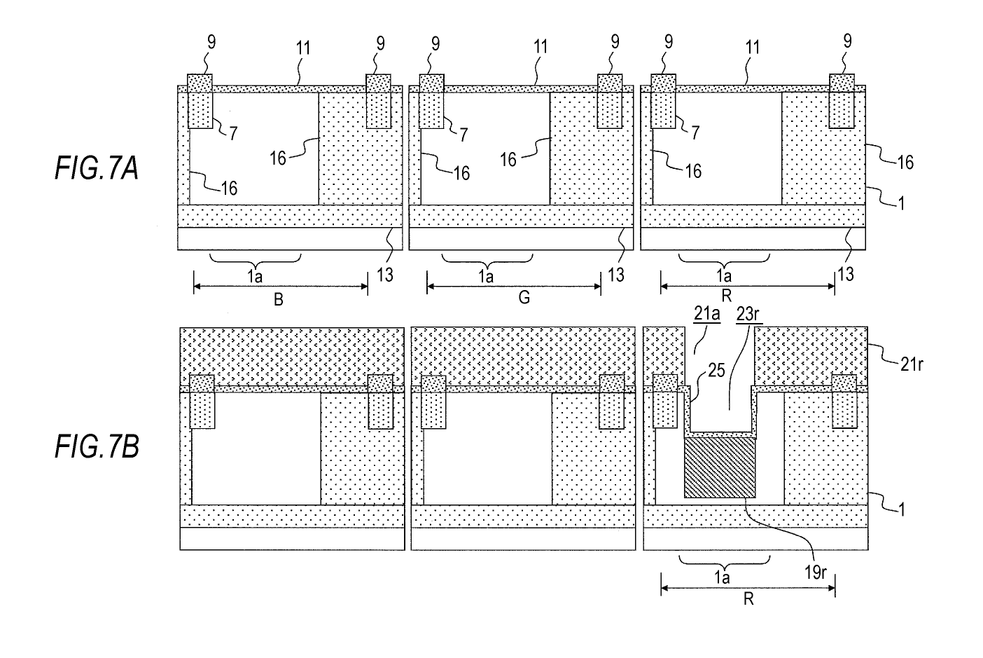

The method of manufacturing a solid-state imaging device according to the second embodiment will be described with reference to the process diagrams shown in FIGS. 7A to 11. The manufacturing method described in this embodiment is a method of forming a solid-state imaging device in which a plurality of photoelectric conversion portions in which the recess portion has a different depth is provided in pixels of each color by using the method according to the first embodiment. In the drawings, the cross-sectional views of the three pixels the red pixel R sensitive to red light, the green pixels G sensitive to green light, and the blue pixel B sensitive to blue light are shown.

First, as shown in FIG. 7A, a diffusion barrier layer 7, a device separation layer 9, a silicon oxide film 11 serving as an implantation-through film, a p-type impurity region 13, and a p-well region 16 are formed on a top surface side of a semiconductor substrate 1 made from single-crystalline silicon. That is to say, the same steps as those described based on FIGS. 1A to 2A in the first embodiment are performed.

Subsequently, as shown in FIG. 7B, a resist pattern 21 is formed so as to cover the green pixel G and the blue pixel B and have an aperture portion 21a on the light-sensitive region 1a of the red pixel R. After that, the silicon oxide film 11 and the top surface of the semiconductor substrate 1 are etched using the resist pattern 21 as a mask, thus forming a recess portion 23r on the top surface of the light-sensitive region 1a in the red pixel R. This etching is carried out by a dry etching such as a RIE (reactive ion etching). Moreover, the recess portion 23r has a depth of about 500 nm to 1 μl.

Subsequently, a silicon oxide film 25 is formed in such a manner as to cover the inner walls of the recess portion 23r, and thereafter, an ion implantation is performed on only the bottom portion of the recess portion 23r, thus selectively forming a n-type impurity region 19r which serves as an impurity region of the first conductivity type. This step may be performed in a manner similar to that described based on FIG. 3B. After this step is completed, the resist pattern 21 is removed.

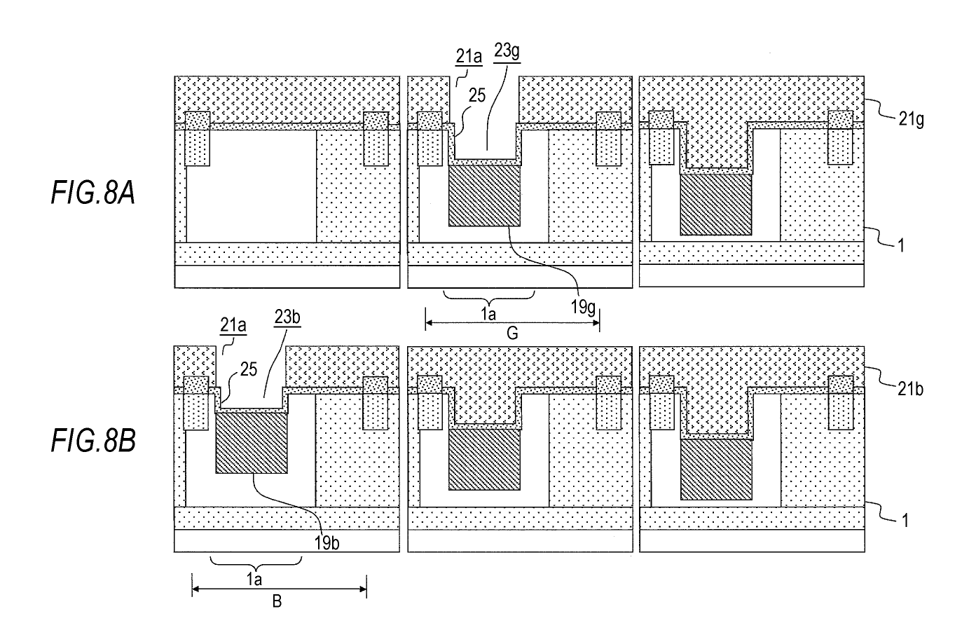

After that, in the steps shown in FIG. 8A, formation of a recess portion 23g, formation of a silicon oxide film 25, and selective formation of an n-type impurity region 19g on the bottom portion of the recess portion 23g are performed with respect to the green pixel G. These steps may be performed in a manner similar to the above-described steps for the red pixel R, and it is important to form the recess portion 23g to a depth smaller than that of the recess portion 23r of the red pixel R.

Moreover, similarly, in the steps shown in FIG. 8B, formation of a recess portion 23b, formation of a silicon oxide film 25, and selective formation of an n-type impurity region 19b on the bottom portion of the recess portion 23b are performed with respect to the blue pixel B. These steps may be performed in a manner similar to the above-described steps for the red pixel R, and it is important to form the recess portion 23b to a depth smaller than that of the recess portions 23r and 23g of the red and green pixels R and G.

In this way, the recess portions 23r, 23g, and 23b are formed on the top surface of the semiconductor substrate 1 in the pixels R, G, and B of each color so that a recess portion in a pixel for sensing longer-wavelength light has a greater depth than that in the other pixels for sensing the shorter-wavelength light. Here, the order of performing the respective steps for the red pixel R, the green pixel G, and the blue pixel B is not particularly limited.

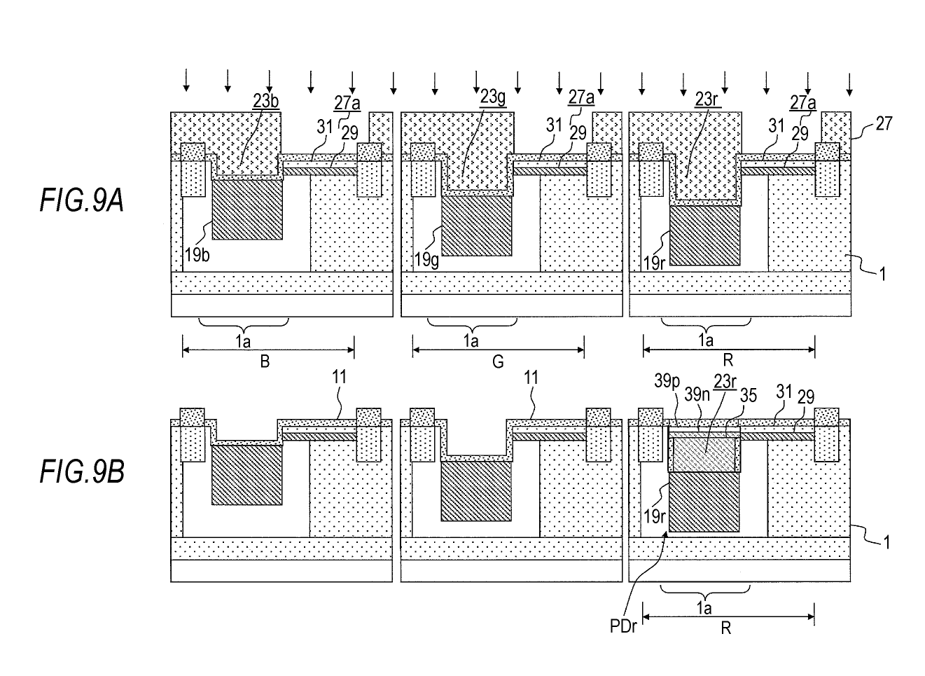

Next, as shown in FIG. 9A, a resist pattern 27 which has aperture portions 27a on regions adjacent to the light-sensitive regions 1a of the respective pixels R, G, and B is formed on the semiconductor substrate 1. Subsequently, by an ion implantation using the resist pattern 27 as a mask, n-type channel regions 29 which serve as channel regions of the first conductivity type are formed on the top surface layer of the semiconductor substrate 1, and surface p-type regions 31 are subsequently formed.

This step is performed in a manner similar to that described based on FIG. 4A in the first embodiment, and the n-type channel regions 29 and the surface p-type regions 31 are formed so as to reach the sidewalls of the recess portion 23 in the respective pixels R, G, and B. After the ion implantation is completed, the resist pattern 27 is removed.

Next, as shown in FIG. 9B, the top surface of the semiconductor substrate 1 in which the n-type impurity region 19r is formed is exposed to the bottom portion of the recess portion 23r that is formed in the red pixel R, and a n-type semiconductor layer 35 is formed so as to be in contact with the n-type impurity region 19r. After that, the n-type channel region 29 on the sidewalls of the recess portion 23r and portions of the semiconductor substrate 1 in which the surface p-type region 31 is formed are exposed, and another n-type semiconductor layer 39n is formed on the n-type semiconductor layer 35 so as to be connected to the n-type channel region 29. Subsequently, a p-type semiconductor layer which becomes a surface p-type region 39p is formed so as to be connected to the surface p-type region 31. At that time, the n-type semiconductor layer 39n and the surface p-type region 39p are grown in that order so that the inside of the recess portion 23r is filled and they are formed to approximately the same height as the top surface of the semiconductor substrate 1. Thereafter, the surface p-type region 39p is covered with a silicon oxide film 41.

In this way, a photodiode PDr in which a photoelectric conversion portion is formed by the n-type impurity region 19r provided under the bottom portion of the recess portion 23r and the n-type semiconductor layers 35 and 39n filling the inside of the recess portion 23r is formed in the light-sensitive region 1a of the red pixel R. Moreover, the surface p-type region 39p on the n-type semiconductor layer 39n serves as a hole-accumulation layer. The above-described steps are performed in a manner similar to those described based on FIGS. 4B to 6B in the first embodiment.

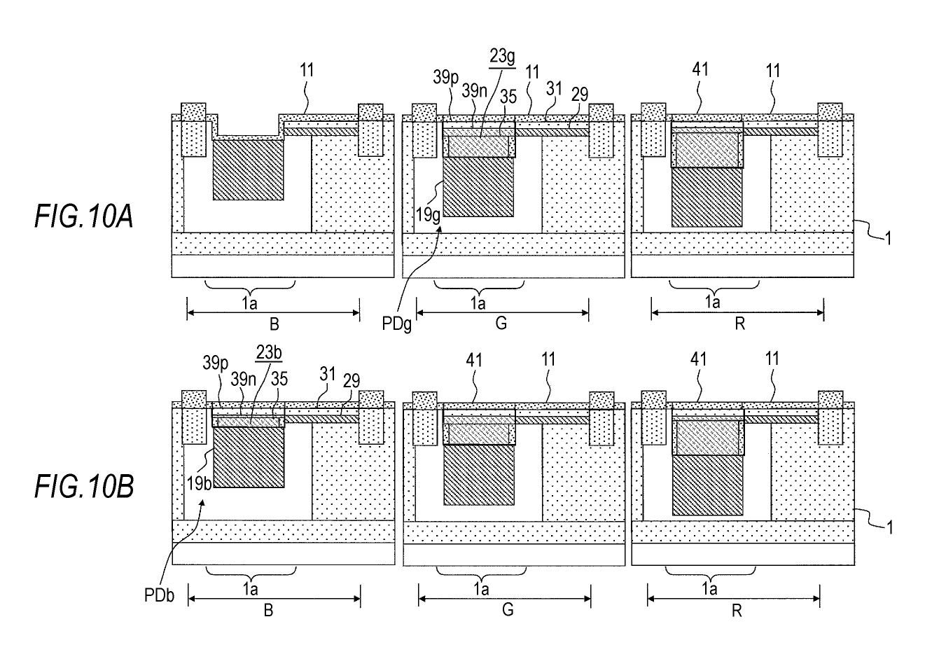

Subsequently, as shown in FIG. 10A, by performing the same steps with respect to the green pixel G, a photodiode PDg is formed in which a photoelectric conversion portion is formed by an n-type impurity region 19g provided under the bottom portion of the recess portion 23g and the n-type semiconductor layers 35 and 39n filling the inside of the recess portion 23g. Moreover, a surface p-type region (p-type semiconductor layer) 39p which serves as a hole-accumulation layer is formed on the n-type semiconductor layer 39n so as to have approximately the same height as the top surface of the semiconductor substrate 1.

In addition, as shown in FIG. 10B, by performing the same steps with respect to the blue pixel B, a photodiode PDb is formed in which a photoelectric conversion portion is formed by an n-type impurity region 19b provided under the bottom portion of the recess portion 23b and the n-type semiconductor layers 35 and 39n filling the inside of the recess portion 23b. Moreover, a surface p-type region (p-type semiconductor layer) 39p which serves as a hole-accumulation layer is formed on the n-type semiconductor layer 39n so as to have approximately the same height as the top surface of the semiconductor substrate 1.

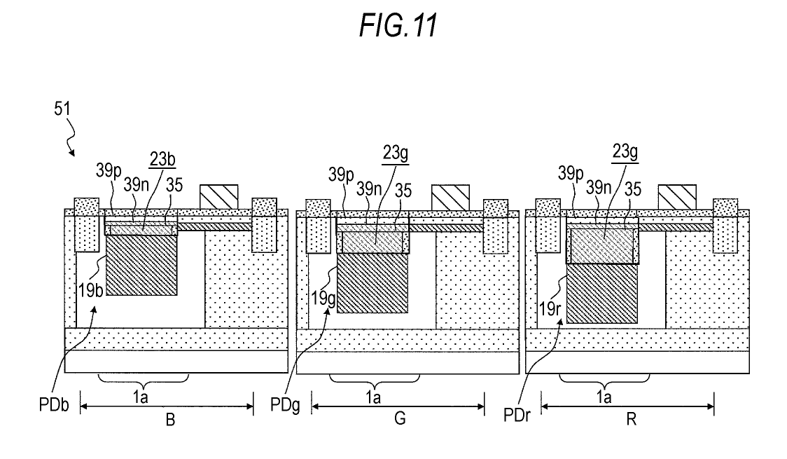

Thereafter, as shown in FIG. 11, read-gate electrodes 43, other necessary gate electrodes, and wirings are formed on a portion of each of the pixels R, G, and B where the n-type channel region 29 and the surface p-type region 31 are laminated. Although not shown in the drawing, in addition to the above-mentioned elements, an optical system including a lens system is formed, and color filters that transmit desired wavelengths of light are formed on the respective light-sensitive regions 1a of the pixels R, G, and B, whereby a solid-state imaging device 51 is produced.

In the respective pixels R, G, and B of each color of the solid-state imaging device 51 produced thus, the photodiodes PDr, PDg, and PDb are provided in which the photoelectric conversion portions are respectively formed by the n-type impurity regions 19r, 19g, and 19b that are disposed under the recess portions 23r, 23g, and 23b formed on the top surface of the semiconductor substrate 1 and the laminated structure of the n-type semiconductor layers 35 and 39n that are provided in the recess portion 23 in a state of being connected to the n-type impurity regions 19r, 19g, and 19b.

When forming the photoelectric conversion portion in such pixels R, G, and B of each color, by performing an impurity diffusion (ion implantation) from the bottom portions of the recess portions 23r, 23g, and 23b that are formed in the semiconductor substrate 1, it is possible to form the n-type impurity regions 19r, 19g, and 19b at a further deeper position in the semiconductor substrate 1. At that time, the depths of the recess portions 23r, 23g, and 23b of the respective pixels R, G, and B are set such that a recess portion in a pixel for sensing longer-wavelength light has a greater depth than that in the other pixels for sensing the shorter-wavelength light. For this reason, in the red pixel R, it is possible to form the photoelectric conversion portion by the n-type impurity region 19r and the n-type semiconductor layers 35 and 39n that are formed at the deepest position.

Furthermore, since the laminated structure of the n-type semiconductor layers 35 and 39n has approximately the same height as the top surface of the semiconductor substrate 1, it is possible to maintain surface flatness of the semiconductor substrate 1.

In this way, similar to the first embodiment, it is becomes easy to form a wiring layer, an optical system, and the like on the semiconductor substrate 1, in which surface flatness is maintained, with high accuracy. Moreover, by the photoelectric conversion portion having a depth that extends from a deeper position of the semiconductor substrate 1 to the top surface thereof, it is possible to sense longer-wavelength light with high sensitivity when red light is received. As a result, high-quality imaging is made possible in miniaturized pixels.

In the second embodiment, the recess portions 23r, 23g, and 23b are provided in the semiconductor substrate 1 in all pixels R, G, and B. However, in the blue pixel B that is configured to sense the shortest-wavelength light, the recess portion may not be provided, and the photoelectric conversion portion may be formed of only the n-type impurity region.

Moreover, in the second embodiment, the same advantage can be obtained as long as after the recess portion is formed, and the n-type impurity region is formed on the bottom portion of the recess portion, the n-type semiconductor layers are formed in the recess portion. Therefore, the order of forming the n-type channel region 29, the surface p-type region 31, and the like is not particularly limited.

### 3. Third Embodiment

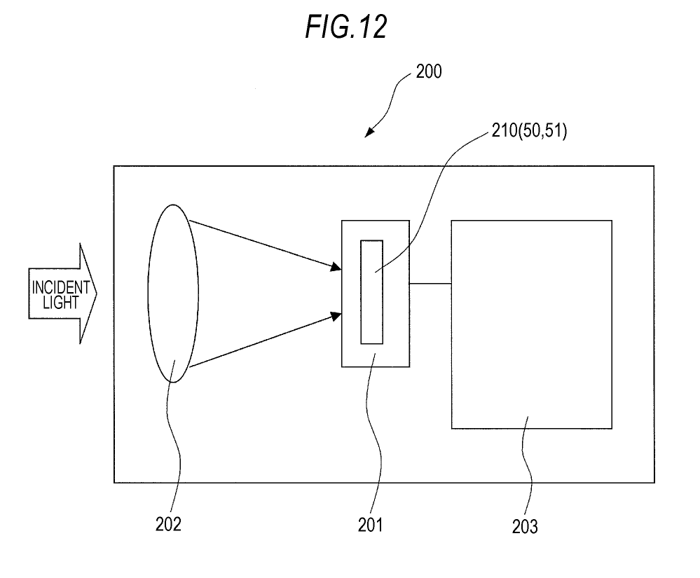

FIG. 12 shows a configuration of an electronic apparatus having the above-described solid-state imaging device as the third embodiment of the present invention.

The electronic apparatus 200 shown in FIG. 12 is provided with a solid-state imaging device 210 in an imaging unit 201. A light-condensing optical unit 202 that condenses an image is provided on a light condensing side of the imaging unit 201. Moreover, the imaging unit 201 is connected to a signal processing unit 203 that includes a driving circuit for driving the imaging unit 201, a signal processing circuit for processing signals having been subjected to photoelectric conversion in the solid-state imaging device 210 to obtain image signals, and other circuits. Moreover, the image signals processed by the signal processing unit 203 are stored in an image storage unit (not illustrated). In such an electronic apparatus 200, the solid-state imaging device 210 may be the solid-state imaging device 50 (51) described in the embodiments.

Since the electronic apparatus 200 uses the solid-state imaging device 50 (51) according to the embodiments of the present invention, it is possible to provide an advantage that images with excellent quality can be obtained.

The electronic apparatus 200 may have such a form that it is formed into a one-chip configuration and may have a modular form having an imaging function in which an imaging unit and a signal processing unit or an optical system are packaged. The electronic apparatus 200 as used herein refers to an overall apparatus having an imaging function and may be a digital camera, a personal computer, a video camera, a television, and a mobile computer represented by a cellular phone. Moreover, “imaging” is meant to not only include capturing of an image at the time of general camera shooting but also detection of fingerprints and the like in a broader sense of its meaning.

The present application contains subject matter related to that disclosed in Japanese Priority Patent Application JP 2009-096610 filed in the Japan Patent Office on Apr. 13, 2009, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

1. A method of manufacturing a solid-state imaging device comprising:
a first step of forming a recess portion on a top surface of a semiconductor substrate;
a second step of selectively forming an impurity region of a first conductivity type in a lower portion of the recess portion by introducing impurities from a bottom surface of the recess portion; and
a third step of forming a semiconductor layer in the recess portion, thus forming a photoelectric conversion portion which includes the impurity region and the semiconductor layer.

2. The method according to claim 1, wherein in the third step, the semiconductor layer is formed in a state where impurities of the first conductivity type are contained in at least a portion of the semiconductor layer being in contact with the impurity region.

3. The method according to claim 1, further comprising, after the third step, a step of introducing impurities of the first conductivity type into at least a portion of the semiconductor layer being in contact with the impurity region.

4. The method according to claim 1, wherein in the third step, the semiconductor layer is formed to the height of the top surface of the semiconductor substrate.

5. The method according to claim 1, wherein a top surface layer of the semiconductor layer has a second conductivity type.

6. The method according to claim 1, wherein in the third step, as the semiconductor layer, crystalline silicon or crystalline silicon-germanium is formed in the recess portion of the semiconductor substrate made from single-crystalline silicon.

7. A solid-state imaging device comprising:
a semiconductor substrate having a recess portion formed on a top surface thereof;
an impurity region of a first conductivity type formed in a portion of the semiconductor substrate disposed lower than a bottom surface of the recess portion; and
a semiconductor layer of the first conductivity type formed in the recess portion,
wherein the impurity region and the semiconductor layer form a photoelectric conversion portion.

8. The solid-state imaging device according to claim 7, wherein a top surface of the semiconductor layer is at the same height as the top surface of the semiconductor substrate.

9. The solid-state imaging device according to claim 7, wherein a top surface layer of the semiconductor layer has a second conductivity type.

10. The solid-state imaging device according to claim 7, wherein:
the semiconductor substrate is made from a single-crystalline silicon; and
the semiconductor layer is made from crystalline silicon or crystalline silicon-germanium.

11. The solid-state imaging device according to claim 7, wherein a photoelectric conversion portion that is formed by only an impurity region of the first conductivity type is formed on a top surface side of the semiconductor substrate together with the photoelectric conversion portion.

12. The solid-state imaging device according to claim 11, the photoelectric conversion portion that is formed of the impurity region and the semiconductor layer is provided as a photoelectric conversion portion for sensing longer-wavelength light than the photoelectric conversion portion that is formed by only the impurity region.

13. The solid-state imaging device according to claim 7, wherein a plurality of photoelectric conversion portions are provided in which the recess portion has a different depth.

14. The solid-state imaging device according to claim 13, wherein the recess portion in the photoelectric conversion portion for sensing longer-wavelength light has a greater depth than that in the other photoelectric conversion portions for sensing shorter-wavelength light.

15. An electronic apparatus including a solid-state imaging device, the solid-state imaging device comprising:
a semiconductor substrate having a recess portion formed on a top surface thereof;
an impurity region of a first conductivity type formed in a portion of the semiconductor substrate disposed lower than a bottom surface of the recess portion; and
a semiconductor layer of a first conductivity type formed in the recess portion,
wherein the impurity region and the semiconductor layer form a photoelectric conversion portion.
